(19) United States
(12) Patent Application Publication
(10) Pub. No.: US 2025/0142845 A1
(43) Pub. Date: May 1, 2025

(54) CATALYTIC METAL PLATE IN A METAL-INSULATOR-METAL CAPACITOR AND METHODS OF FORMING THE SAME

(71) Applicant: Taiwan Semiconductor Manufacturing Company Limited, Hsinchu (TW)

(72) Inventors: Kuen-Yi Chen, Hsinchu City (TW); Yi Ching Ong, Hsinchu (TW); Wei Ting Hsieh, Hsinchu (TW); Yu-Wei Ting, Taipei City (TW); Kuo-Ching Huang, Hsinchu City (TW)

(21) Appl. No.: 18/641,416

(22) Filed: Apr. 21, 2024

Related U.S. Application Data
(60) Provisional application No. 63/594,042, filed on Oct. 30, 2023.

(51) Int. Cl. H01L 23/522

(52) U.S. Cl. CPC H10D 1/692; H01L 23/5223

(57) ABSTRACT

A device structure includes a first electrode overlying a substrate; a node dielectric contacting the first electrode and including a dielectric material having a dielectric constant greater than 30; and a second electrode contacting the node dielectric. A first one of the first electrode and the second electrode includes a first catalytic metal plate in direct contact with the node dielectric and having a first electronegativity that is not greater than an electronegativity of molybdenum.

### RELATED APPLICATIONS

This application claims the benefit of priority from U.S. Provisional Application No. 63/594,042 entitled “Capacitor Having a Large Capacitance” filed on Oct. 30, 2023, the entire contents of which are hereby incorporated by reference for all purposes.

### BACKGROUND

Formation of a high-capacitance capacitor in semiconductor dies benefits from the formation of a thin node dielectric having a high dielectric constant. However, dielectric materials providing high dielectric constants exhibit deterioration of crystalline quality at a low thickness range. This is because the fraction of the dielectric material that crystallizes into a desirable symmetric crystalline phase decreases as the thickness of the dielectric material decreases. As a result, a thin dielectric material layer used as a node dielectric of a capacitor structure tends to exhibit a low effective dielectric constant due to inferior crystallinity than a highly crystalline bulk dielectric material having a same material composition.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1F are sequential vertical cross-sectional views of a first embodiment structure during manufacturing according to an embodiment of the present disclosure.

FIGS. 2A-2F are vertical cross-sectional views of various configurations of a capacitor structure according to embodiments of the present disclosure.

FIGS. 3A-3E are sequential vertical cross-sectional views of a second embodiment structure during manufacturing according to an embodiment of the present disclosure.

FIG. 4 is a schematic circuit diagram of the first embodiment structure according to an embodiment of the present disclosure.

FIG. 5 is a circuit diagram of the second embodiment structure according to an embodiment of the present disclosure.

FIG. 6 illustrate examples of symmetric crystalline structures that may be used for the dielectric material of the node dielectric of various embodiments of the present disclosure.

FIG. 7 is a line graph that illustrates the dependency of the dielectric constant of a node dielectric as a function of thickness and crystallinity.

FIG. 8 is a flowchart that illustrates a sequence of processing steps for manufacturing various embodiment resistive memory devices of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. Drawings are not drawn to scale. Elements with the same reference numerals refer to the same element, and are presumed to have the same material composition and the same thickness range unless expressly indicated otherwise. Embodiments are expressly contemplated in which multiple instances of any described element are repeated unless expressly stated otherwise. Embodiments are expressly contemplated in which non-essential elements are omitted even if such embodiments are not expressly disclosed but are known in the art.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. Ordinals, such as “first,” “second,” “third,” etc., are merely adjectives, and are not a part of a unique name for any structural element. As such, an element identified with a particular ordinal (such as “first”) in the specification may be identified with a different ordinal (such as “second”) or with a different adjective (such as “additional,” “another,” etc.). As an example, a limitation such as “a first one of the first electrode and the second electrode comprises a first catalytic metal plate” means that any one of the two electrodes may include a catalytic metal plate, which is referred to as a “first catalytic metal plate” for an identification purpose only.

Device scaling of a memory cell using a capacitor as a charge storage elements may be impacted by decreasing the electrical oxide thickness (EOT) of a node dielectric. Many node dielectric materials that provide a high dielectric constant have a crystalline structure. Such node dielectric materials provide a higher dielectric constant in crystalline states relative to amorphous states. Simple reduction of the physical thickness of such node dielectric materials results in reduced crystallinity, which reduces the dielectric constant of the node dielectric and reduces the capacitance of the capacitor. Typically, thin dielectric materials which may provide high dielectric constants greater than 30 (which are commonly referred to as super-high k materials) in crystalline states do not easily crystallize below a certain threshold thickness, which is herein referred to as a critical thickness. The critical thickness depends on the dielectric material, but is generally in a range from 3 nm to 5 nm.

According to an aspect of the present disclosure, at least one catalytic metal layer may be formed directly on a dielectric material that provides a higher dielectric constant in a crystalline phase relative to an amorphous phase. The at least one catalytic metal layer comprises a metal having a low electronegativity, which may be not greater than the electronegativity of molybdenum (which is 2.16), and/or not greater than 1.80, and/or not greater than 1.50, and/or not greater than 1.20, and/or not greater than 1.00. The low electronegativity of the metal in the at least one catalytic metal layer induces catalytic crystallization of the dielectric material at a lower temperature than a minimum anneal temperature that would be required for crystallization of the dielectric material in the absence of a catalytic metal. Generally, the lower the electronegativity of the metal in the at least one catalytic metal layer, the more effective the at least one catalytic metal layer is in inducing transition of the amorphous phase of the dielectric material into a crystalline phase. Various embodiment methods of the present disclosure may be effectively used for back-end-of-line (BEOL) metal-insulator-metal capacitors, which may be formed using back-end-of-line processing steps and generally do not use any temperature higher than 400 degrees Celsius. Thus, various embodiment methods of the present disclosure may be used to form a capacitor providing a higher capacitance through engineering of the crystalline state of a node dielectric material for memory devices. Various embodiments of the present disclosure are now described with reference to accompanying drawings herebelow.

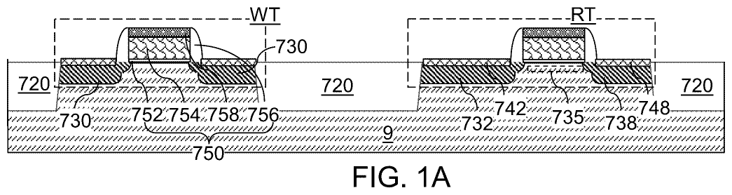

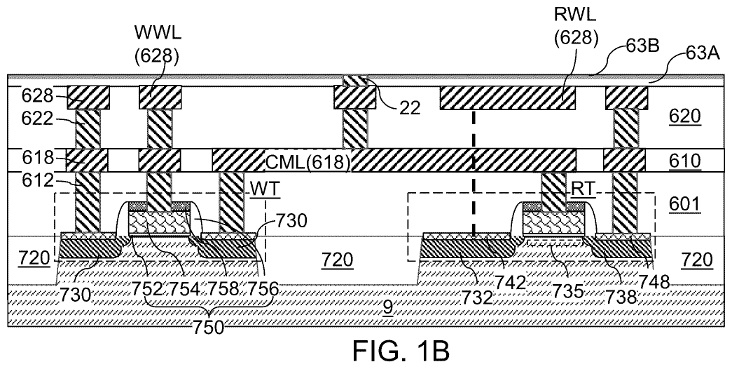

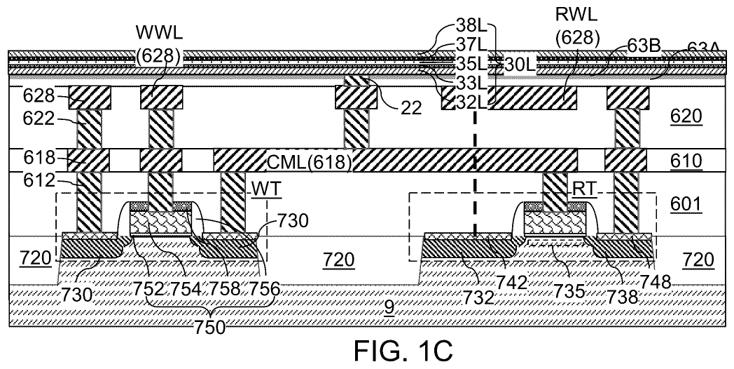

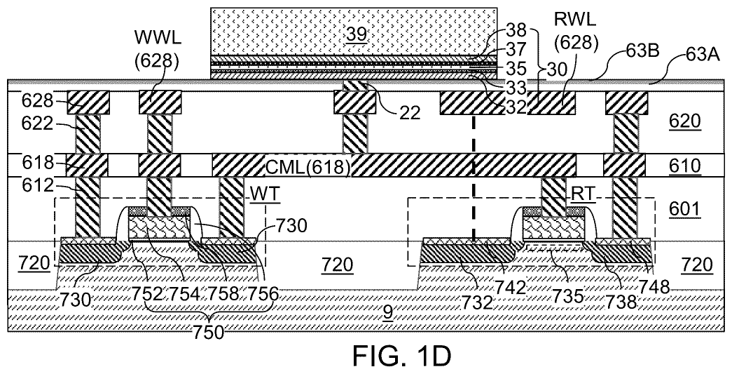

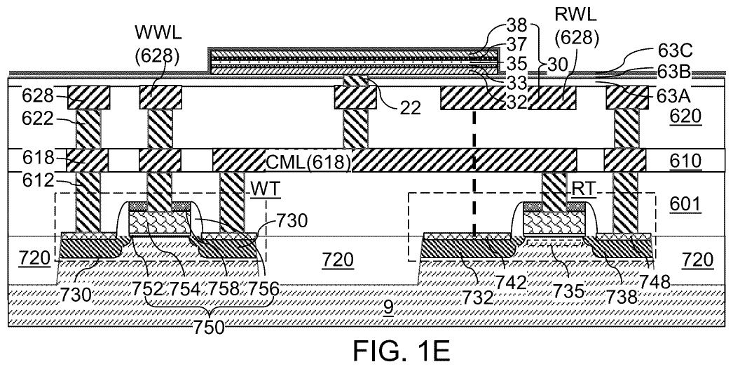

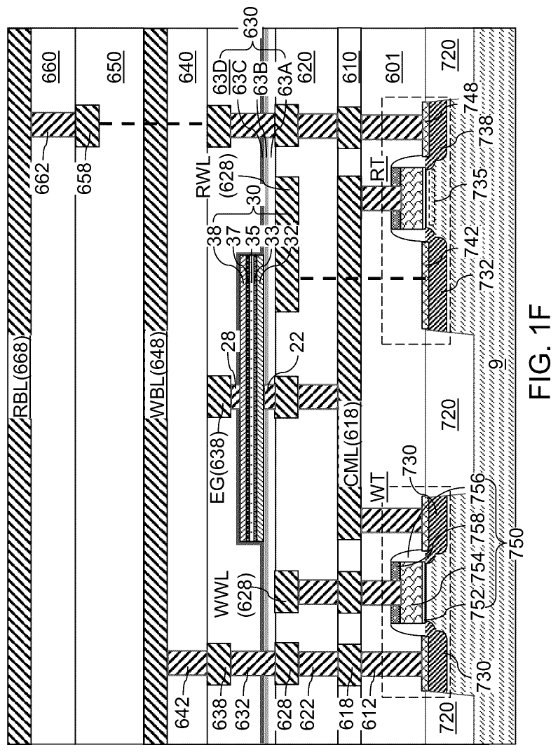

FIGS. 1A-1F are sequential vertical cross-sectional views of a first embodiment structure during manufacturing according to an embodiment of the present disclosure. While a single device region for a gain cell memory device is illustrated in FIGS. 1A-1F, it is understood that a two-dimensional array of gain cell memory devices may be formed by repeating the illustrated structures along horizontal directions as a two-dimensional array.

Referring to FIG. 1A, the first embodiment structure includes a substrate 9, which may be a semiconductor substrate such as a commercially available silicon wafer. Shallow trench isolation structures 720 including a dielectric material such as silicon oxide may be formed in an upper portion of the substrate 9. Suitable doped semiconductor wells, such as p-type wells and n-type wells, may be formed within each area that may be laterally enclosed by a portion of the shallow trench isolation structures 720. Field effect transistors may be formed over the top surface of the substrate 9. For example, each field effect transistor may include a source region 732, a drain region 738, a semiconductor channel 735 that includes a surface portion of the substrate 9 extending between the source region 732 and the drain region 738, and a gate structure 750. In some embodiments, a pair of source/drain regions 730 may be formed in lieu of a source region 732 and a drain region 738. A source/drain region 730 refers to a region that may be used as a source region or a drain region depending on the configuration of the electrical bias voltages applied to a field effect transistor.

Each gate structure 750 may include a gate dielectric 752, a gate electrode 754, a gate cap dielectric 758, and a dielectric gate spacer 756. A source-side metal-semiconductor alloy region 742 may be formed on each source region 732, and a drain-side metal-semiconductor alloy region 748 may be formed on each drain region 738. A metal-semiconductor alloy region formed on a source/drain region 730 is herein referred to as a source/drain metal semiconductor alloy region. The field effect transistors may be formed in any configuration known in the art. For example, the field effect transistors may comprise planar field effect transistors, fin field effect transistors, gate-all-around (GAA) field effect transistors, and/or any other type of field effect transistors.

The illustrated region of the first embodiment structure corresponds to a region of a gain cell memory device. In the first embodiment structure, each gain cell memory device may comprise a first field effect transistor (such as a write transistor WT) and a second field effect transistor (such as a read transistor RT) that are formed on the top surface of the substrate 9.

Referring to FIG. 1B, dielectric material layers and metal interconnect structures may be formed over the field effect transistors (WT, RT). The dielectric material layers may comprise, for example, a contact-level dielectric material layer 601, a first metal-line-level dielectric material layer 610, a second line-and-via-level dielectric material layer 620, a via-level dielectric layer 63A, and a planar passivation dielectric layer 63B. The contact-level dielectric material layer 601, the first metal-line-level dielectric material layer 610, the second line-and-via-level dielectric material layer 620, and the via-level dielectric layer 63A may be collectively referred to as first dielectric material layers (601, 610, 620, 63A). Each of the contact-level dielectric material layer 601, the first metal-line-level dielectric material layer 610, the second line-and-via-level dielectric material layer 620, and the via-level dielectric layer 63A may comprise an interlayer dielectric (ILD) material such as undoped silicate glass, a doped silicate glass, and/or porous or non-porous organosilicate glass. The planar passivation dielectric layer 63B comprises a dielectric diffusion barrier material such as silicon nitride, silicon carbide nitride, silicon carbide oxide, silicon oxynitride, or a combination thereof. The thickness of the planar passivation dielectric layer 63B may be selected to be sufficient to block diffusion of a metal to be used for a catalytic metal layer. For example, the thickness of the planar passivation dielectric layer 63B may be in a range from 5 nm to 30 nm, although lesser and greater thicknesses may also be used.

The metal interconnect structures are formed in the first dielectric material layers (601, 610, 620, 63A) and the planar passivation dielectric layer 63B. The metal interconnect structures are herein referred to as first metal interconnect structures (612, 618, 622, 628, 22). The first metal interconnect structures (612, 618, 622, 628, 22) may comprise device contact via structures 612 formed in the contact-level dielectric material layer 601 and contact a respective component of semiconductor devices on the substrate 9, first metal line structures 618 formed in the first metal-line-level dielectric material layer 610, first metal via structures 622 formed in a lower portion of the second line-and-via-level dielectric material layer 620, second metal line structures 628 formed in an upper portion of the second line-and-via-level dielectric material layer 620, and bottom electrode contact via structures 22 that are formed through the planar passivation dielectric layer 63B and the via-level dielectric layer 63A. Each of the first metal interconnect structures (612, 618, 622, 628, 22) may include at least one conductive material, which may be a combination of a metallic liner layer (such as a metallic nitride or a metallic carbide) and a metallic fill material. Each metallic liner layer may include TiN, TaN, WN, TiC, TaC, and WC, and each metallic fill material portion may include W, Cu, Al, Co, Ru, Mo, Ta, Ti, alloys thereof, and/or combinations thereof.

According to an aspect of the present disclosure, a subset of the first metal interconnect structures (612, 618, 622, 628, 22) within the region of a gain cell memory device electrically connects a source/drain region 730 of the first field effect transistor (such as a write transistor WT), a gate electrode 754 of the second field effect transistor (such as a read transistor RT, and the first electrode (32 and/or 33), and a bottom electrode contact via structure 22 (which is subsequently electrically connected to a first electrode of a capacitor). In one embodiment, the first metal interconnect structures (612, 618, 622, 628, 22) may comprise a connection metal line CML that laterally extends between the first field effect transistor (such as the write transistor WT) and the second field effect transistor (such as the read transistor RT) and contacting a top surface of a first device contact via structure 612 electrically connected to, and overlying, a first source/drain region 730 of the first field effect transistor, and contacting a top surface of a second device contact via structure 612 electrically connected to, and overlying, a gate electrode 754 of the second field effect transistor.

In one embodiment, the first metal interconnect structures (612, 618, 622, 628, 22) may comprise write word lines WWL, which are metal lines used as the word lines of the write transistors WT. In one embodiment, the write word lines WWL may comprise a subset of the second metal line structures 628. In one embodiment, the first metal interconnect structures (612, 618, 622, 628, 22) may comprise read word lines RWL, which are metal lines used as the word lines of the read transistors RT. In one embodiment, the read word lines RWL may comprise a subset of the second metal line structures 628. Each read word line RWL may be electrically connected to source regions 732 within a respective row of read transistors RT by electrically conductive paths (represented as a dotted line in FIG. 1B) embodied as a respective subset of the first metal interconnect structures (612, 618, 622, 628, 22) (such as a respective subset of the device contact via structures 612, the first metal line structures 618, and the first metal via structures 622).

Referring to FIG. 1C, a material layer stack 30L may be deposited over the top surface of the planar passivation dielectric layer 63B. The material layer stack 30L may comprise, from bottom to top, a bottom non-catalytic material layer 32L including a non-catalytic conductive material, a bottom catalytic metal layer 33L including a catalytic metal, a node dielectric material layer 35L, a top catalytic metal layer 37L including another catalytic metal, and a top non-catalytic material layer 38L including another non-catalytic conductive material. As used herein, a catalytic metal refers to a metal that has an electronegativity that is not greater than the electronegatively of molybdenum, which is 2.16. A catalytic metal in contact with a dielectric material in an amorphous state may function as a catalyst during a phase transition of the amorphous state to a crystalline state if stable phases of the dielectric material include a crystalline state. Generally, the lower the electronegativity of the catalytic metal, the more effective the catalytic metal is in inducting the phase transition.

Non-catalytic conductive materials refers to conductive materials that do not induce catalytic crystallization for a dielectric metal oxide. Non-catalytic conductive materials comprise metals having electronegativity greater than the electronegativity of molybdenum, metallic compounds that are chemically stable and do not include phase transitions in a dielectric material, and conductive metal oxides. Exemplary metallic compounds which are non-catalytic conductive materials include tungsten nitride, titanium nitride, tantalum nitride, and molybdenum nitride. Exemplary conductive metal oxides that may be used as a non-catalytic conductive material include, for example, indium tin oxide, fluorine-doped tin oxide, zinc oxide, tungsten oxide (WO₃), etc.

In one embodiment, the non-catalytic conductive materials of the bottom non-catalytic material layer 32L and the top non-catalytic material layer 38L may comprise at least one non-radioactive metal with a respective electronegativity greater than the electronegativity of molybdenum, which is 2.16. For example, at least one of the non-catalytic conductive materials of the bottom non-catalytic material layer 32L and the top non-catalytic material layer 38L may be independently selected from a set of elemental metals consisting of gold (Au) with the electronegativity of 2.54, tungsten (W) with the electronegativity of 2.36, platinum (Pt) with the electronegativity of 2.28, iridium (Ir) with the electronegativity of 2.20, and osmium (Os) with the electronegativity of 2.20. Alternatively or additionally, at least one of the non-catalytic conductive materials of the bottom non-catalytic material layer 32L and the top non-catalytic material layer 38L may be independently selected from conductive metallic nitride materials including tungsten nitride, titanium nitride, tantalum nitride, and molybdenum nitride.

The thickness of each of the bottom non-catalytic material layer 32L and the top non-catalytic material layer 38L may be in a range from 5 nm to 30 nm, such as from 10 nm to 25 nm, although lesser and greater thicknesses may also be used. Each of the bottom non-catalytic material layer 32L and the top non-catalytic material layer 38L may be deposited by physical vapor deposition, chemical vapor deposition, or atomic layer deposition.

In one embodiment, the catalytic metals of the bottom catalytic metal layer 33L and the top catalytic metal layer 37L may comprise non-radioactive metallic materials with a respective electronegativity that is not greater than the electronegativity of molybdenum. In one embodiment, the catalytic metals of the bottom catalytic metal layer 33L and the top catalytic metal layer 37L may comprise, and/or may consist essentially of, a respective elemental metal with a respective electronegativity that is not greater than the electronegativity of molybdenum. In one embodiment, each catalytic metal of the bottom catalytic metal layer 33L and the top catalytic metal layer 37L may comprise, and/or may consist essentially of, an alkaline earth metal, an alkali metal, a post-transition metal, a transition metal, or a metalloid, and may have an electronegativity that is not greater than the electronegativity of molybdenum.

Alkali metals having electronegativity that is not greater than the electronegativity of molybdenum include lithium (Li) with electronegativity of 0.98, sodium (Na) with electronegativity of 0.93, potassium (K) with electronegativity of 0.82, rubidium (Rb) with electronegativity of 0.82, and cesium (Cs) with electronegativity of 0.79. Alkaline earth metals having electronegativity that is not greater than the electronegativity of molybdenum include beryllium (Be) having electronegativity of 1.57, magnesium (Mg) having electronegativity of 1.31, calcium (Ca) having electronegativity of 1.00, strontium (Sr) having electronegativity of 0.95, and barium (Ba) having electronegativity of 0.89. Post-transition metals having electronegativity that is not greater than the electronegativity of molybdenum include aluminum (Al) with electronegativity of 1.61, gallium (Ga) with electronegativity of 1.81, indium (In) with electronegativity of 1.78, and thallium (Tl) with electronegativity of 1.83. Transition metals having electronegativity that is not greater than the electronegativity of molybdenum include lanthanum (La) with electronegativity of 1.10, cerium (Ce) with electronegativity of 1.12, praseodymium (Pr) with electronegativity of 1.13, neodymium (Nd) with electronegativity of 1.14, samarium (Sm) with electronegativity of 1.17, europium (Eu) with electronegativity of 1.15, gadolinium (Gd) with electronegativity of 1.20, terbium (Tb) with electronegativity of 1.20, dysprosium (Dy) with electronegativity of 1.22, holmium (Ho) with electronegativity of 1.23, erbium (Er) with electronegativity of 1.24, thulium (Tm) with electronegativity of 1.25, ytterbium (Yb) with electronegativity of 1.10, and lutetium (Lu) with electronegativity of 1.23. Metalloids having electronegativity that is not greater than the electronegativity of molybdenum include germanium (Ge) with electronegativity of 1.81, arsenic (As) with electronegativity of 2.05, antimony (Sb) with electronegativity of 2.06, and tellurium (Te) with electronegativity of 2.1.

In one embodiment, the catalytic metals of the bottom catalytic metal layer 33L and the top catalytic metal layer 37L may comprise non-radioactive metallic materials with a respective electronegativity that is not greater than 1.80. In one embodiment, the catalytic metals of the bottom catalytic metal layer 33L and the top catalytic metal layer 37L may comprise, and/or may consist essentially of, a respective elemental metal with a respective electronegativity that is not greater than 1.80. In one embodiment, each catalytic metal of the bottom catalytic metal layer 33L and the top catalytic metal layer 37L may comprise, and/or may consist essentially of, an alkaline earth metal, an alkali metal, a post-transition metal, or a transition metal, and may have an electronegativity that is not greater than 1.80.

Alkali metals having electronegativity that is not greater than 1.80 include lithium (Li) with electronegativity of 0.98, sodium (Na) with electronegativity of 0.93, potassium (K) with electronegativity of 0.82, rubidium (Rb) with electronegativity of 0.82, and cesium (Cs) with electronegativity of 0.79. Alkaline earth metals having electronegativity that is not greater than 1.80 include beryllium (Be) having electronegativity of 1.57, magnesium (Mg) having electronegativity of 1.31, calcium (Ca) having electronegativity of 1.00, strontium (Sr) having electronegativity of 0.95, and barium (Ba) having electronegativity of 0.89. Post-transition metals having electronegativity that is not greater than 1.80 include aluminum (Al) with electronegativity of 1.61, and indium (In) with electronegativity of 1.78. Transition metals having electronegativity that is not greater than 1.80 include lanthanum (La) with electronegativity of 1.10, cerium (Ce) with electronegativity of 1.12, praseodymium (Pr) with electronegativity of 1.13, neodymium (Nd) with electronegativity of 1.14, samarium (Sm) with electronegativity of 1.17, europium (Eu) with electronegativity of 1.15, gadolinium (Gd) with electronegativity of 1.20, terbium (Tb) with electronegativity of 1.20, dysprosium (Dy) with electronegativity of 1.22, holmium (Ho) with electronegativity of 1.23, erbium (Er) with electronegativity of 1.24, thulium (Tm) with electronegativity of 1.25, ytterbium (Yb) with electronegativity of 1.10, and lutetium (Lu) with electronegativity of 1.23.

In one embodiment, the catalytic metals of the bottom catalytic metal layer 33L and the top catalytic metal layer 37L may comprise non-radioactive metallic materials with a respective electronegativity that is not greater than 1.50. In one embodiment, the catalytic metals of the bottom catalytic metal layer 33L and the top catalytic metal layer 37L may comprise, and/or may consist essentially of, a respective elemental metal with a respective electronegativity that is not greater than 1.50. In one embodiment, each catalytic metal of the bottom catalytic metal layer 33L and the top catalytic metal layer 37L may comprise, and/or may consist essentially of, an alkaline earth metal, an alkali metal, or a transition metal, and may have an electronegativity that is not greater than 1.50.

Alkali metals having electronegativity that is not greater than 1.50 include lithium (Li) with electronegativity of 0.98, sodium (Na) with electronegativity of 0.93,potassium (K) with electronegativity of 0.82, rubidium (Rb) with electronegativity of 0.82, and cesium (Cs) with electronegativity of 0.79. Alkaline earth metals having electronegativity that is not greater than 1.50 include magnesium (Mg) having electronegativity of 1.31, calcium (Ca) having electronegativity of 1.00, strontium (Sr) having electronegativity of 0.95, and barium (Ba) having electronegativity of 0.89. Transition metals having electronegativity that is not greater than 1.50 include lanthanum (La) with electronegativity of 1.10, cerium (Ce) with electronegativity of 1.12, praseodymium (Pr) with electronegativity of 1.13, neodymium (Nd) with electronegativity of 1.14, samarium (Sm) with electronegativity of 1.17, europium (Eu) with electronegativity of 1.15, gadolinium (Gd) with electronegativity of 1.20, terbium (Tb) with electronegativity of 1.20, dysprosium (Dy) with electronegativity of 1.22, holmium (Ho) with electronegativity of 1.23, erbium (Er) with electronegativity of 1.24, thulium (Tm) with electronegativity of 1.25, ytterbium (Yb) with electronegativity of 1.10, and lutetium (Lu) with electronegativity of 1.23.

In one embodiment, the catalytic metals of the bottom catalytic metal layer 33L and the top catalytic metal layer 37L may comprise non-radioactive metallic materials with a respective electronegativity that is not greater than 1.20. In one embodiment, the catalytic metals of the bottom catalytic metal layer 33L and the top catalytic metal layer 37L may comprise, and/or may consist essentially of, a respective elemental metal with a respective electronegativity that is not greater than 1.20. In one embodiment, each catalytic metal of the bottom catalytic metal layer 33L and the top catalytic metal layer 37L may comprise, and/or may consist essentially of, an alkaline earth metal, an alkali metal, or a transition metal, and may have an electronegativity that is not greater than 1.20.

Alkali metals having electronegativity that is not greater than 1.20 include lithium (Li) with electronegativity of 0.98, sodium (Na) with electronegativity of 0.93, potassium (K) with electronegativity of 0.82, rubidium (Rb) with electronegativity of 0.82, and cesium (Cs) with electronegativity of 0.79. Alkaline earth metals having electronegativity that is not greater than 1.20 include calcium (Ca) having electronegativity of 1.00, strontium (Sr) having electronegativity of 0.95, and barium (Ba) having electronegativity of 0.89. Transition metals having electronegativity that is not greater than 1.20 include lanthanum (La) with electronegativity of 1.10, cerium (Ce) with electronegativity of 1.12, praseodymium (Pr) with electronegativity of 1.13, neodymium (Nd) with electronegativity of 1.14, samarium (Sm) with electronegativity of 1.17, europium (Eu) with electronegativity of 1.15, and ytterbium (Yb) with electronegativity of 1.10.

In one embodiment, the catalytic metals of the bottom catalytic metal layer 33L and the top catalytic metal layer 37L may comprise non-radioactive metallic materials with a respective electronegativity that is not greater than 1.00. In one embodiment, the catalytic metals of the bottom catalytic metal layer 33L and the top catalytic metal layer 37L may comprise, and/or may consist essentially of, a respective elemental metal with a respective electronegativity that is not greater than 1.00. In one embodiment, each catalytic metal of the bottom catalytic metal layer 33L and the top catalytic metal layer 37L may comprise, and/or may consist essentially of, an alkaline earth metal or an alkali metal, and may have an electronegativity that is not greater than 1.00.

Alkali metals having electronegativity that is not greater than 1.00 include lithium (Li) with electronegativity of 0.98, sodium (Na) with electronegativity of 0.93, potassium (K) with electronegativity of 0.82, rubidium (Rb) with electronegativity of 0.82, and cesium (Cs) with electronegativity of 0.79. Alkaline earth metals having electronegativity that is not greater than 1.00 include strontium (Sr) having electronegativity of 0.95, and barium (Ba) having electronegativity of 0.89.

In one embodiment, the catalytic metals of the bottom catalytic metal layer 33L and the top catalytic metal layer 37L may comprise non-radioactive metallic materials with a respective electronegativity that is not greater than 0.90. In one embodiment, the catalytic metals of the bottom catalytic metal layer 33L and the top catalytic metal layer 37L may comprise, and/or may consist essentially of, a respective elemental metal with a respective electronegativity that is not greater than 0.90. In one embodiment, each catalytic metal of the bottom catalytic metal layer 33L and the top catalytic metal layer 37L may comprise, and/or may consist essentially of, an alkaline earth metal or an alkali metal, and may have an electronegativity that is not greater than 0.90.

Alkali metals having electronegativity that is not greater than 0.90 include potassium (K) with electronegativity of 0.82, rubidium (Rb) with electronegativity of 0.82, and cesium (Cs) with electronegativity of 0.79. Alkaline earth metals having electronegativity that is not greater than 1.00 include barium (Ba) having electronegativity of 0.89.

In one embodiment, the catalytic metals of the bottom catalytic metal layer 33L and the top catalytic metal layer 37L may comprise a non-radioactive metallic material with a respective electronegativity that is not greater than 0.80. In one embodiment, the catalytic metals of the bottom catalytic metal layer 33L and the top catalytic metal layer 37L may comprise, and/or may consist essentially of, an elemental metal with a respective electronegativity that is not greater than 0.80. In one embodiment, each catalytic metal of the bottom catalytic metal layer 33L and the top catalytic metal layer 37L may comprise, and/or may consist essentially of, an alkali metal having an electronegativity that is not greater than 0.80. The alkali metal having electronegativity that is not greater than 0.80 is cesium (Cs) with electronegativity of 0.79. A non-radioactive isotope of cesium is cesium 133. In one embodiment, the catalytic metals of the bottom catalytic metal layer 33L and the top catalytic metal layer 37L may consist essentially of cesium 133.

Each of the bottom catalytic metal layer 33L and the top catalytic metal layer 37L may have a thickness in a range from 2 nm to 30 nm, such as from 4 nm to 15 nm, although lesser and greater thicknesses may also be used. Each of the bottom catalytic metal layer 33L and the top catalytic metal layer 37L may be deposited by physical vapor deposition, chemical vapor deposition, or atomic layer deposition.

The node dielectric material layer 35L comprises a dielectric material that has a crystalline phase having a dielectric constant greater than 30, and preferably having a dielectric constant greater than 35. Exemplary dielectric materials that may be used for the node dielectric material layer 35L of various embodiments of the present disclosure include perovskite oxides materials, hafnium based oxides, zirconium-based oxides, and titanium based oxides. Perovskite oxide material include barium titanate (BaTiO₃), strontium titanate (SrTiO₃), lead zirconate titanate (PZT), barium strontium titanate (BST), lead titanate (PbTiO₃), etc. Perovskite oxide materials may have a dielectric constant in a range from 30 to 1,000 in a crystalline phase. Hafnium-based oxides include hafnium dioxide (HfO₂), hafnium oxynitride, and hafnium silicate (HfSiO₄), and may have a dielectric constant in a range from 30 to 40 in a crystalline state. Zirconium-based oxides include zirconium dioxide (ZrO₂), zirconium oxynitride, and zirconium silicate (ZrSiO₄), and may have a dielectric constant in a range from 30 to 35 in a crystalline state. Titanium-based oxides include titanium dioxide (TiO₂) or titanium oxynitride, and may have a dielectric constant in a range from 80 to 150. Generally, these materials provide a higher dielectric constant in crystalline phases than in amorphous phases.

The node dielectric material layer 35L may have a thickness in a range from 2 nm to 10 nm, such as from 3 nm to 8 nm. It is noted that exceeding the upper limit of the thickness range for the node dielectric material layer 35L may hinder achieving the target capacitance value of the capacitor, while variations in the thickness of the top and bottom electrodes do not significantly impact the capacitance. Lesser and greater thicknesses of the node dielectric material layer 35L may also be used, depending on the specific application requirements. The node dielectric material layer 35L may be deposited in an amorphous phase or in a partially crystalline phase using physical vapor deposition. The volume fraction of the amorphous dielectric material in the node dielectric material layer 35L may be in a range from 20% to 100%, and/or in a range from 50% to 95%, and/or in a range from 70% to 90%.

Referring to FIG. 1D, a photoresist layer 39 may be applied over the top non-catalytic material layer 38L, and may be lithographically patterned into a two-dimensional array of photoresist material portions covering a respective area that overlies a respective bottom electrode contact via structure 22. Generally, the area of each photoresist material portion within the two-dimensional array of photoresist material portions may be in a range from 40% to 90% of the area of each gain cell memory device in a plan view. The material layer stack 30L including the bottom non-catalytic material layer 32L, the bottom catalytic metal layer 33L, the node dielectric material layer 35L, the top catalytic metal layer 37L, and the top non-catalytic material layer 38L may be patterned into a two-dimensional array of capacitor structures 30, for example, by performing an anisotropic etch process that etches unmasked potions of the layer stack using the patterned photoresist material portions as an etch mask.

Each capacitor structure 30 comprises a first electrode (32, 33) which is also referred to as a bottom electrode, a node dielectric 35 which is a patterned portion of node dielectric material layer 35L, and a second electrode (37, 38) which is also referred to as a top electrode. The first electrode (32, 33) comprises a bottom non-catalytic material plate 32 and a bottom catalytic metal plate 33. The bottom non-catalytic material plate 32 comprises a patterned portion of the bottom non-catalytic material layer 32L. The bottom catalytic metal plate 33 comprises a patterned portion of the bottom catalytic metal layer 33L. The node dielectric 35 comprises a patterned portion of the node dielectric material layer 35L. The second electrode (37, 38) comprises a top catalytic metal plate 37 and a top non-catalytic material plate 38. The top catalytic metal plate 37 is a patterned portion of the top catalytic metal layer 37L. The top non-catalytic material plate 38 is a patterned portion of the top non-catalytic material layer 38L.

Generally, a stack of a first electrode (32, 33), a node dielectric 35, and a second electrode (37, 38) may be formed over the first dielectric material layers (601, 610, 620, 63A). The first electrode (32, 33) is formed on a top surface of one of the first metal interconnect structures (612, 618, 622, 628, 22). The node dielectric 35 comprises an amorphous phase dielectric material and may further comprise a partially-crystalline dielectric material having a same material composition as the amorphous phase dielectric material. The volume fraction of the amorphous phase dielectric material in the node dielectric 35 may be in a range from 20% to 100%, such as from 50% to 100%, and/or from 60% to 95%, although lesser and greater percentages may also be used. At least one catalytic metal plate, such as the bottom catalytic metal plate 33 and the top catalytic metal plate 37, may be in direct contact with the node dielectric 35. Each catalytic metal plate (33, 37) comprises, and/or consists essentially of, a metal having an electronegativity that is not greater than an electronegativity of molybdenum. The photoresist layer 39 can be subsequently removed, for example, by ashing.

Referring to FIG. 1E, a conformal passivation dielectric layer 63C may be deposited over the capacitor structures 30 and the planar passivation dielectric layer 63B. The conformal passivation dielectric layer 63C comprises a dielectric diffusion barrier material such as silicon nitride, silicon carbide nitride, silicon carbide oxide, silicon oxynitride, or a combination thereof. The thickness of the conformal passivation dielectric layer 63C may be selected to be sufficient to block diffusion of the catalytic metal(s) in the bottom catalytic metal plate 33 and the top catalytic metal plate 37. For example, the thickness of the conformal passivation dielectric layer 63C may be in a range from 5 nm to 30 nm, although lesser and greater thicknesses may also be used.

The conformal passivation dielectric layer 63C may contact the top surface of each second electrode (37, 38), and may contact each sidewall of the first electrodes (32, 33), the node dielectrics 35, and the second electrodes (37, 38). The planar passivation dielectric layer 63B may contact the bottom surface of each first electrode (32, 33). The two-dimensional array of capacitor structures 30 may be encapsulated by the conformal passivation dielectric layer 63C, the planar passivation dielectric layer 63B, and the two-dimensional array of bottom electrode contact via structures 22.

Referring to FIG. 1F, a capacitor-level dielectric layer 63D, a fourth line-and-via-level dielectric material layer 640, a fifth line-and-via-level dielectric material layer 650, a sixth line-and-via-level dielectric material layer 660, and additional dielectric material layers (not shown) may be formed over the conformal passivation dielectric layer 63C. The set of dielectric material layers that are formed above the conformal passivation dielectric layer 63C is herein referred to as second dielectric material layers (63D, 640, 650, 660). The set of all dielectric material layers between the second line-and-via-level dielectric material layer 620 and the fourth line-and-via-level dielectric material layer 640 (excluding the node dielectrics 35) constitutes a third line-and-via-level dielectric material layer 630. Thus, the third line-and-via-level dielectric material layer 630 may comprise the via-level dielectric layer 63A, the planar passivation dielectric layer 63B, the conformal passivation dielectric layer 63C, and the capacitor-level dielectric layer 63D.

Second metal interconnect structures (28, 632, 638, 642, 648, 658, 662, 668) are formed in the second dielectric material layers (63D, 640, 650, 660). The second metal interconnect structures (28, 632, 638, 642, 648, 658, 662, 668) may comprise top electrode contact via structures 28 contacting a top surface of a respective top electrode (37, 38) and formed through the capacitor-level dielectric layer 63D and the conformal passivation dielectric layer 63C, second metal via structures 632 formed in a lower portion of the third line-and-via-level dielectric material layer 630, third metal line structures 638 formed in an upper portion of the third line-and-via-level dielectric material layer 630, third metal via structures 642 formed in a lower portion of the fourth line-and-via-level dielectric material layer 640, fourth metal line structures 648 formed in an upper portion of the fourth line-and-via-level dielectric material layer 640, fourth metal via structures (not illustrated) formed in a lower portion of the fifth line-and-via-level dielectric material layer 650, fifth metal line structures 658 formed in an upper portion of the fifth line-and-via-level dielectric material layer 650, fifth metal via structures 662 formed in a lower portion of the sixth line-and-via-level dielectric material layer 660, sixth metal line structures 668 formed in an upper portion of the sixth line-and-via-level dielectric material layer 660, etc.

The second metal interconnect structures (28, 632, 638, 642, 648, 658, 662, 668) may comprise write bit lines WBL and read bit lines RBL. Each write bit line WBL may be electrically connected to second source/drain regions 730 of a column of write transistors WT through a respective subset of the second metal interconnect structures (28, 632, 638, 642, 648, 658, 662, 668) and a respective subset of the first metal interconnect structures (612, 618, 622, 628, 22). Each read bit line RBL may be electrically connected to drain regions 738 of a column of read transistors RT through a respective subset of the second metal interconnect structures (28, 632, 638, 642, 648, 658, 662, 668) and a respective subset of the first metal interconnect structures (612, 618, 622, 628, 22). A set of second metal interconnect structures (28, 632, 638, 642, 648, 658, 662, 668) that is used as components of an electrically conductive path between a read bit lien RBL and a drain region 738 of a read transistor RT and located between a third metal line structure 638 and a fifth metal line structure 658 is schematically represented as a dotted line.

In one embodiment, each top electrode (37, 38) may be electrically connected to electrical ground through a respective subset of the second metal interconnect structures (28, 632, 638, 642, 648, 658, 662, 668) that includes a respective top electrode contact via structure 28. The subset of the second metal interconnect structures (28, 632, 638, 642, 648, 658, 662, 668) comprises electrically grounded interconnect structures EG.

The node dielectrics 35 in the capacitor structures 30 are subjected to thermal cycling during formation of the second dielectric material layers (63D, 640, 650, 660) and the second metal interconnect structures (28, 632, 638, 642, 648, 658, 662, 668). Processing steps generally known as back-end-of-line (BEOL) processing steps may be used to form the second dielectric material layers (63D, 640, 650, 660) and the second metal interconnect structures (28, 632, 638, 642, 648, 658, 662, 668). The maximum temperature of the BEOL processing steps is typically not higher than 400 degrees Celsius. Thus, the anneal effect on the crystallinity of the dielectric material in the node dielectrics 35 depends on the effectiveness of the catalytic metals in the catalytic metal plates (33, 37). According to an aspect of the present disclosure, the low electronegativity of the catalytic metals in the catalytic metal plates (33, 37) provides sufficient catalytic effect for conversion of an amorphous-phase dielectric material in the node dielectrics 35 into a crystalline dielectric material. The phase change of the dielectric material in the node dielectrics 35 from an amorphous phase into a crystalline phase increases the dielectric constant of the node dielectrics 35, and thus, increases the capacitance of each capacitor structure 30.

Generally, the dielectric material of the node dielectrics 35 may be annealed such that the catalytic metal plates (33, 37) induce catalytic crystallization of the amorphous phase dielectric material in the node dielectrics 35 into a crystalline dielectric material having a dielectric constant greater than 30, and preferably greater than 35. In one embodiment, the anneal of the dielectric material of the node dielectrics 35 may be effected by the BEOL processing steps used to form the second dielectric material layers (63D, 640, 650, 660) and the second metal interconnect structures (28, 632, 638, 642, 648, 658, 662, 668).

In one embodiment, the crystalline structure in each node dielectric 35 may comprise a symmetrical crystal structure that provides an enhanced dielectric constant relative to an amorphous material having a same material composition. In one embodiment, a predominant volume fraction of the dielectric material in each node dielectric 35 is in a symmetrical crystal structure selected from a cubic crystal structure, a tetragonal crystal structure, and a hexagonal crystal structure. As used herein, a “predominant volume fraction” refers to a volume fraction, i.e., a fraction as measured in volume, that is at least 50%. In one embodiment, the predominant volume fraction may comprise at least 80%, and/or at least 90%, and/or at least 95%, of an entire volume of a node dielectric 35.

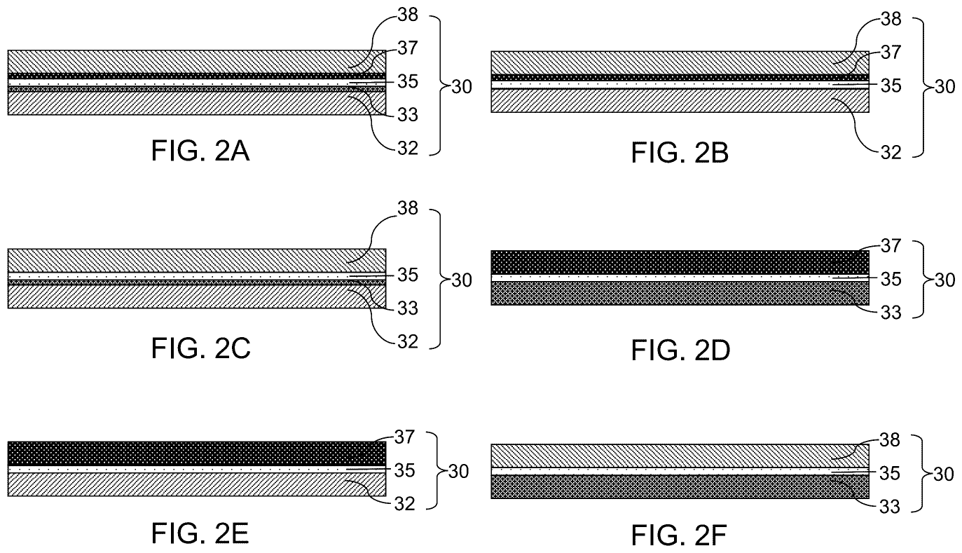

FIGS. 2A-2F are vertical cross-sectional views of various configurations of a capacitor structure 30 according to embodiments of the present disclosure.

Referring to FIG. 2A, a first configuration of the capacitor structure 30 is illustrated, which may be the same as the configuration of the capacitor structure as described with reference to FIGS. 1C-1F.

Referring to FIG. 2B, a second configuration of the capacitor structure 30 is illustrated, which may be derived from the first configuration of the capacitor structure 30 described with reference to FIGS. 1C-1F and 2A by omitting the bottom catalytic metal plate 33. In this embodiment, the first electrode, or the bottom electrode, may consist of a bottom non-catalytic material plate 32. Catalytic crystallization of the amorphous dielectric material in the node dielectrics 35 into a crystalline phase may be effected by the top catalytic metal plate 37.

Referring to FIG. 2C, a third configuration of the capacitor structure 30 is illustrated, which may be derived from the first configuration of the capacitor structure 30 described with reference to FIGS. 1C-1F and 2A by omitting the top catalytic metal plate 37. In this embodiment, the second electrode, or the top electrode, may consist of a top non-catalytic material plate 38. Catalytic crystallization of the amorphous dielectric material in the node dielectrics 35 into a crystalline phase may be effected by the bottom catalytic metal plate 33.

Referring to FIG. 2D, a fourth configuration of the capacitor structure 30 is illustrated, which may be derived from the first configuration of the capacitor structure 30 described with reference to FIGS. 1C-1F and 2A by omitting the bottom non-catalytic material plate 32 and the top non-catalytic material plate 38. In this embodiment, the first electrode, or the bottom electrode, may consist of a bottom catalytic metal plate 33; and the second electrode, or the top electrode, may consist of a top catalytic metal plate 37. Catalytic crystallization of the amorphous dielectric material in the node dielectrics 35 into a crystalline phase may be effected by the bottom catalytic metal plate 33 and the top catalytic metal plate 37. The thickness of the bottom catalytic metal plate 33 and the thickness of the top catalytic metal plate 37 may be increased such that the bottom electrode (which consists of the bottom catalytic metal plate 33) has a thickness in a range from 15 nm to 40 nm, and the top electrode (which consists of the top catalytic metal plate 37) has a thickness in a range from 15 nm to 40 nm.

Referring to FIG. 2E, a fifth configuration of the capacitor structure 30 is illustrated, which may be derived from the fourth configuration of the capacitor structure 30 illustrated in FIG. 2D by replacing the bottom catalytic metal plate 33 with a bottom non-catalytic material plate 32. In this embodiment, the first electrode, or the bottom electrode, consists of the bottom non-catalytic material plate 32. Catalytic crystallization of the amorphous dielectric material in the node dielectrics 35 into a crystalline phase may be effected by the top catalytic metal plate 37.

Referring to FIG. 2F, a sixth configuration of the capacitor structure 30 is illustrated, which may be derived from the fourth configuration of the capacitor structure 30 illustrated in FIG. 2D by replacing the top catalytic metal plate 37 with a top non-catalytic material plate 38. In this embodiment, the second electrode, or the top electrode, consists of the top non-catalytic material plate 38. Catalytic crystallization of the amorphous dielectric material in the node dielectrics 35 into a crystalline phase may be effected by the bottom catalytic metal plate 33.

For each of the configurations illustrated in FIGS. 2A-2F, the dielectric material of the node dielectric 35 may be annealed such that the first catalytic metal plate (33 or 37) and the second catalytic metal plate (37 or 33), if present, induce(s) catalytic crystallization of the amorphous phase dielectric material into a crystalline dielectric material having a dielectric constant greater than 30.

Referring collectively to FIGS. 2A-2F, a capacitor structure 30 of various embodiments of the present disclosure may include a first electrode (32 and/or 33) overlying a substrate 9; a node dielectric 35 contacting the first electrode (32 and/or 33) and comprising a dielectric material having a dielectric constant greater than 30; and a second electrode (37 and/or 38) contacting the node dielectric 35. A first one of the first electrode (32 and/or 33) and the second electrode (37 and/or 38) comprises a first catalytic metal plate (33 or 37) in direct contact with the node dielectric 35 and having a first electronegativity that is not greater than an electronegativity of molybdenum.

In one embodiment, a predominant volume fraction of the dielectric material is in a symmetrical crystal structure selected from a cubic crystal structure, a tetragonal crystal structure, and a hexagonal crystal structure. In one embodiment, the predominant volume fraction comprises at least 80% of an entire volume of the node dielectric 35.

In one embodiment, a second one of the first electrode (32 and/or 33) and the second electrode (37 and/or 38) comprises a second catalytic metal plate (37 or 33) and having a second electronegativity that is not greater than the electronegativity of molybdenum. In one embodiment, the second catalytic metal plate (37 or 33) is in direct contact with the node dielectric 35. In one embodiment, the first one of the first electrode (32 and/or 33) and the second electrode (37 and/or 38) further comprises a first non-catalytic material plate (32 or 38) having a third electronegativity that is greater the electronegativity of molybdenum and spaced from the node dielectric 35 by the first catalytic metal plate (33 or 37). In one embodiment, the second one of the first electrode (32 and/or 33) and the second electrode (37 and/or 38) comprises a second non-catalytic material plate (38 or 32) having a fourth electronegativity that is greater the electronegativity of molybdenum and spaced from the node dielectric 35 by the second catalytic metal plate (37 or 33).

In one embodiment, a capacitor structure 30 of various embodiments of the present disclosure may include a first electrode (32 and/or 33) overlying a substrate 9; a node dielectric 35 contacting the first electrode (32 and/or 33) and comprising a dielectric material, wherein a predominant volume fraction of the dielectric material is in a symmetrical crystal structure selected from a cubic crystal structure, a tetragonal crystal structure, and a hexagonal crystal structure; and a second electrode (37 and/or 38) contacting the node dielectric 35. A first one of the first electrode (32 and/or 33) and the second electrode (37 and/or 38) comprises a first catalytic metal plate (33 or 37) in direct contact with the node dielectric 35 and comprising a metal having a first electronegativity not greater than 1.50. In one embodiment, the first catalytic metal plate (33 or 37) comprises an alkali metal or an alkaline earth metal. In one embodiment, a second one of the first electrode (32 and/or 33) and the second electrode (37 and/or 38) comprises a second catalytic metal plate (37 or 33) and having a second electronegativity that is not greater than 1.50.

In one embodiment, a planar passivation dielectric layer 63B contacts a bottom surface of the first electrode (32 and/or 33); and a conformal passivation dielectric layer 63C contacts a top surface of the second electrode (37 and/or 38) and contacts sidewalls of the first electrode (32 and/or 33), the node dielectric 35, and the second electrode (37 and/or 38). In one embodiment, second metal interconnect structures (28, EG) may be provided, which electrically connect the second electrode (37 and/or 38) and electrical ground.

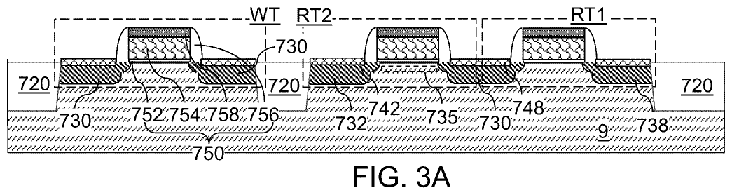

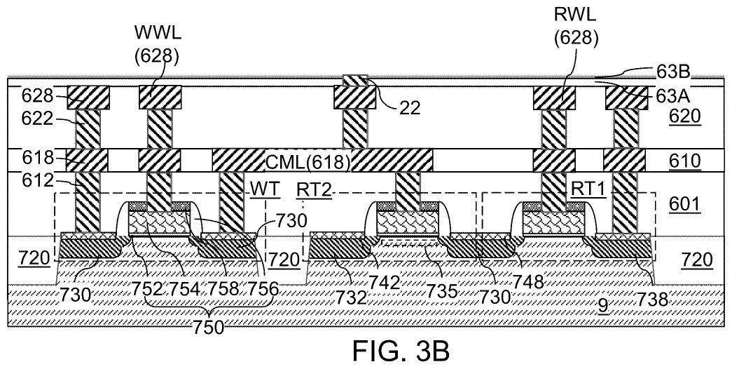

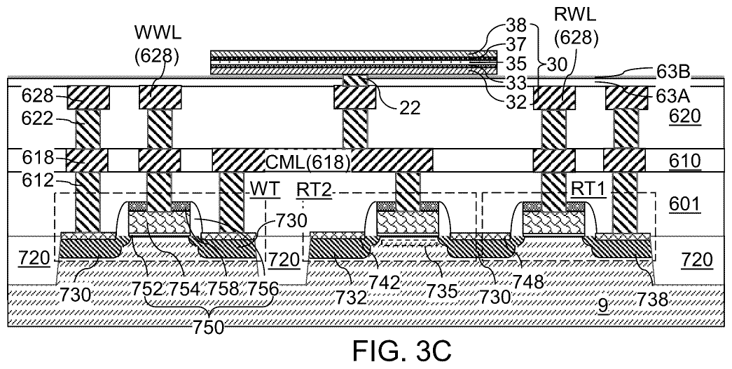

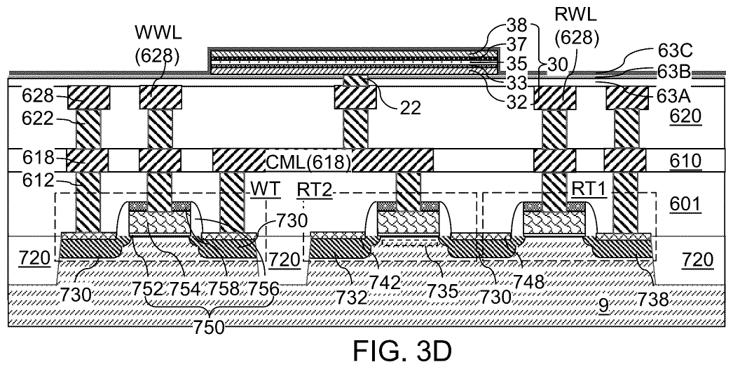

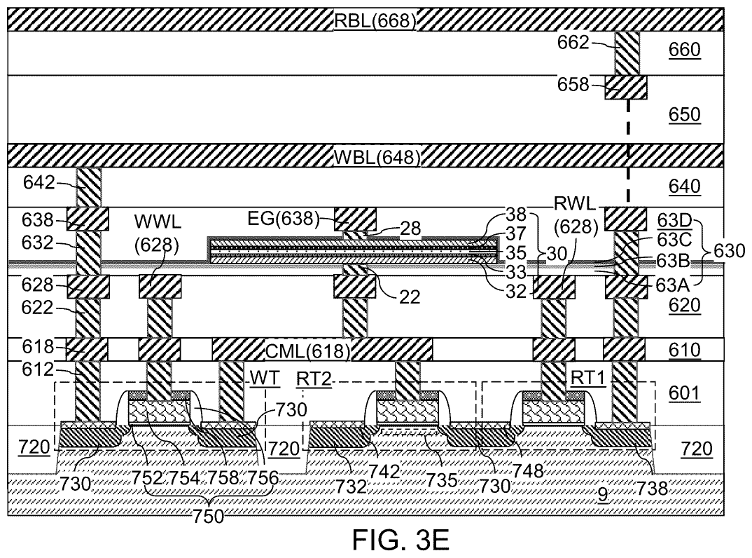

FIGS. 3A-3E are sequential vertical cross-sectional views of a second embodiment structure during manufacturing according to an embodiment of the present disclosure. While a single device region for a gain cell memory device is illustrated in FIGS. 3A-3E, it is understood that a two-dimensional array of gain cell memory devices may be formed by repeating the illustrated structures along horizontal directions as a two-dimensional array.

Referring to FIG. 3A, the second embodiment structure may be derived from the first embodiment structure illustrated in FIG. 1A by forming a series connection of a first read transistor RT1 and a second read transistor RT2 in lieu of a read transistor RT illustrated in FIG. 1A. In this embodiment, the first read transistor RT1 and the second read transistor RT2 may share a source/drain region 730, which is herein referred to as a common source/drain region. The first read transistor RT1 may comprise a drain region 738, and the second read transistor RT2 may comprise a source region 732.

Referring to FIG. 3B, the processing steps described with reference to FIG. 1B may be performed with suitable modifications in the pattern of the first metal interconnect structures (612, 618, 622, 628, 22). In one embodiment, the first metal interconnect structures (612, 618, 622, 628, 22) may comprise a connection metal line CML that laterally extends between a first field effect transistor (such as the write transistor WT) and a second field effect transistor (such as the second read transistor RT2) and contacting a top surface of a first device contact via structure 612 electrically connected to, and overlying, a first source/drain region 730 of the first field effect transistor, and contacting a top surface of a second device contact via structure 612 electrically connected to, and overlying, a gate electrode 754 of the second field effect transistor. In one embodiment, the source region 732 of the second field effect transistor (such as the second read transistor RT2) may be electrically grounded.

In one embodiment, the first metal interconnect structures (612, 618, 622, 628, 22) may comprise write word lines WWL, which are metal lines used as the word lines of the write transistors WT. In one embodiment, the write word lines WWL may comprise a subset of the second metal line structures 628. In one embodiment, the first metal interconnect structures (612, 618, 622, 628, 22) may comprise read word lines RWL, which are metal lines used as the word lines of the first read transistors RT1. In one embodiment, the read word lines RWL may comprise a subset of the second metal line structures 628. Each read word line RWL may be electrically connected to gate electrodes 754 within a respective row of first read transistors RT1.

Referring to FIG. 3C, the processing steps described with reference to FIGS. 1C and 1D may be performed to form a capacitor structure 30 within each area of a gain cell memory device. Optionally, one or two layers within the capacitor structure 30 may be omitted to provide alternative configurations described with reference to FIGS. 2B-2F. Generally, the capacitor structure 30 may be formed in any configuration described with reference to FIGS. 2A-2F.

Referring to FIG. 3D, the processing steps described with reference to FIG. 1E may be performed to form a conformal passivation dielectric layer 63C.

Referring to FIG. 3E, the processing steps described with reference to FIG. 1F may be performed with optional modifications in the wiring pattern of the second metal interconnect structures (28, 632, 638, 642, 648, 658, 662, 668).

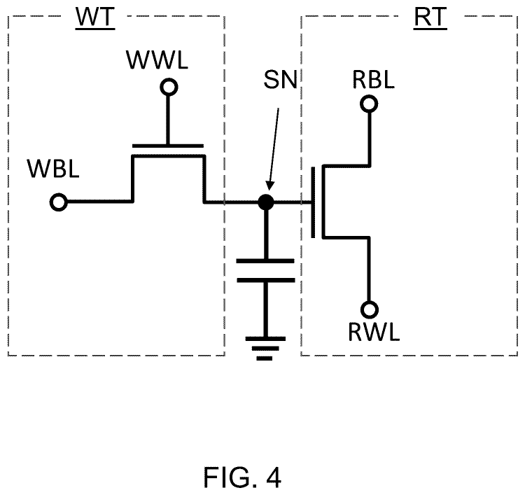

Referring to FIG. 4, a schematic circuit diagram of the first embodiment structure illustrated in FIG. 1F is illustrated. The signal node SN corresponds to the node at which the first source/drain region 730 of the first field effect transistor (which is the write transistor WT), a gate electrode 754 of the second field effect transistor (which is the read transistor RT), and the bottom electrode (32 and/or 33) of a capacitor structure 30 are electrically connected to one another by a connection metal line CML (illustrated in FIGS. 1B-1F). The write bit line WBL is used to provide a bias signal representing the data bit to be encoded in the signal node SN during a write operation. The write word line WWL is used to control switching of the write transistor WT such that the write operation may be performed only when the write transistor is turned on. The read word line RWL and the read bit line RBL may be electrically biased to keep the read transistor RT turned off except during a read operation. The read bit line RBL may be pre-charged to a read-bit-line bias voltage (which is also referred to as a pre-charge bias voltage) during a read operation, and the read word line RWL may be electrically biased during the read operation such that the read transistor RT is turned on if the data bit stored in the signal node SN is “1,” but is not turned on if the if the data bit stored in the signal node SN is “0.” The stored data bit at the signal node SN may be read by determining whether the measured voltage at the read bit line RBL is higher than, or lower than, a predetermined threshold voltage after the read transistor RT is turned on. In embodiments in which the measured voltage at the read bit line RBL is lower than the predetermined threshold voltage after the read operation due to a current through the read transistor RT, the measured data bit is “1.” In embodiments in which the measured voltage at the read bit line RBL is above the predetermined threshold voltage after the read operation, the measured data bit is “0.”

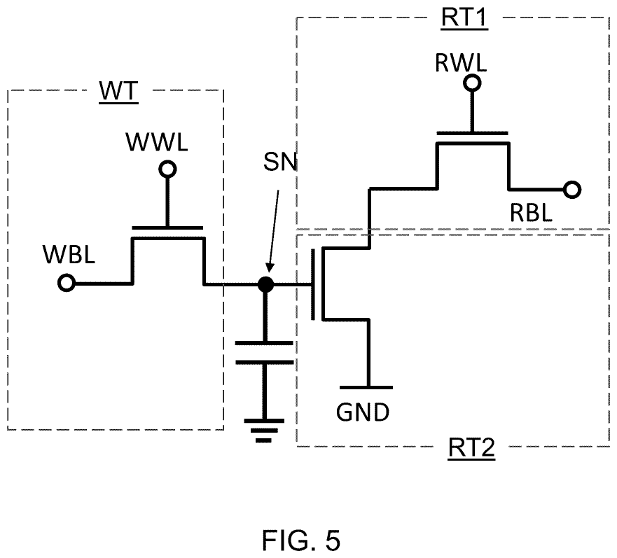

Referring to FIG. 5, a schematic circuit diagram of the second embodiment structure illustrated in FIG. 3E is illustrated. The signal node SN corresponds to the node at which the first source/drain region 730 of the first field effect transistor (which is the write transistor WT), a gate electrode 754 of the second field effect transistor (which is the second read transistor RT2), and the bottom electrode (32 and/or 33) of a capacitor structure 30 are electrically connected to one another by a connection metal line CML (illustrated in FIGS. 3B-3E). The write bit line WBL is used to provide a bias signal representing the data bit to be encoded in the signal node SN during a write operation. The write word line WWL is used to control switching of the write transistor WT such that the write operation may be performed only when the write transistor is turned on. The source region 732 of the second read transistor RT2 is electrically grounded. The read word line RWL may be electrically biased to keep the first read transistor RT1 turned off except during a read operation. The read bit line RBL may be pre-charged to a read-bit-line bias voltage (which is also referred to as a pre-charge bias voltage) during a read operation, and the read word line RWL may be electrically biased during the read operation to turn on the first read transistor RT1. The second read transistor RT2 is turned on if the data bit stored in the signal node SN is “1,” but is not turned on if the if the data bit stored in the signal node SN is “0.” The stored data bit at the signal node SN may be read by determining whether the measured voltage at the read bit line RBL is higher than, or lower than, a predetermined threshold voltage after the first read transistor RT1 is turned on. In embodiments in which the measured voltage at the read bit line RBL is lower than the predetermined threshold voltage after the read operation due to a current through the second read transistor RT2, the measured data bit is “1.” In embodiments in which the measured voltage at the read bit line RBL is above the predetermined threshold voltage after the read operation, the measured data bit is “0.”

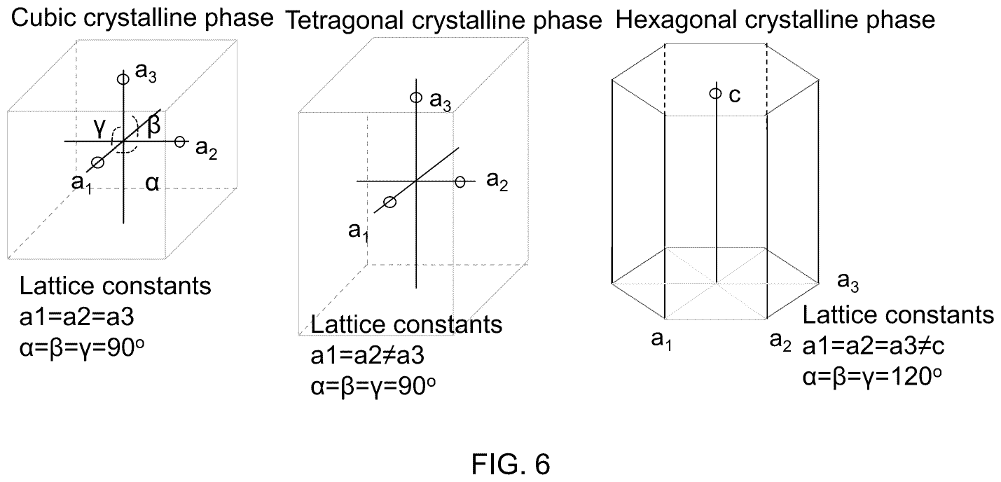

FIG. 6 illustrate examples of symmetric crystalline structures that may be used for the dielectric material of the node dielectric 35 of various embodiments of the present disclosure. Generally, a symmetric crystalline phase of the dielectric material of the node dielectric 35 may provide a higher dielectric constant than an amorphous phases of the dielectric material of the node dielectric 35. Such symmetric crystalline phases include the cubic crystalline phase, the tetragonal crystalline phase, and the hexagonal crystalline phase.

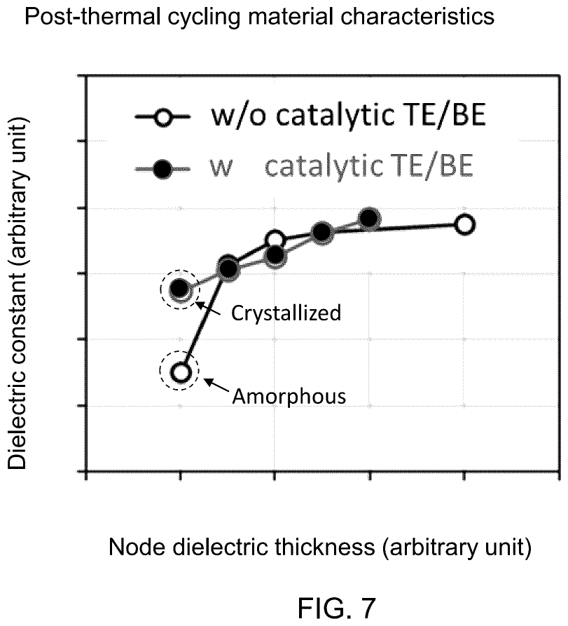

Referring to FIG. 7, dependency of the dielectric constant of a node dielectric 35 as a function of thickness and crystallinity is illustrated. White circles correspond to data points for samples that do not use any catalytic metal in the top electrode (TE) or in the bottom electrode (BE). Black circles correspond to data points for samples that use at least one catalytic metal plate (33 or 37) in the top electrode and/or in the bottom electrode. The thermal cycling represents typical thermal cycling in BEOL processing steps, i.e., thermal cycling up to a maximum temperature not higher than 400 degrees Celsius. The critical thickness below which the crystallinity and the dielectric constant of a node dielectric 35 diverges depending on presence or absence of a catalytic metal plate in a top electrode or in a bottom electrode corresponds to a thickness in a range from 3 nm to 5 nm, such as 4 nm. As illustrated, incorporation of a catalytic metal in the top electrode (TE) or in the bottom electrode (BE) results in a higher dielectric constant for the node dielectric 35, and results in a higher capacitance in a low dielectric thickness range.

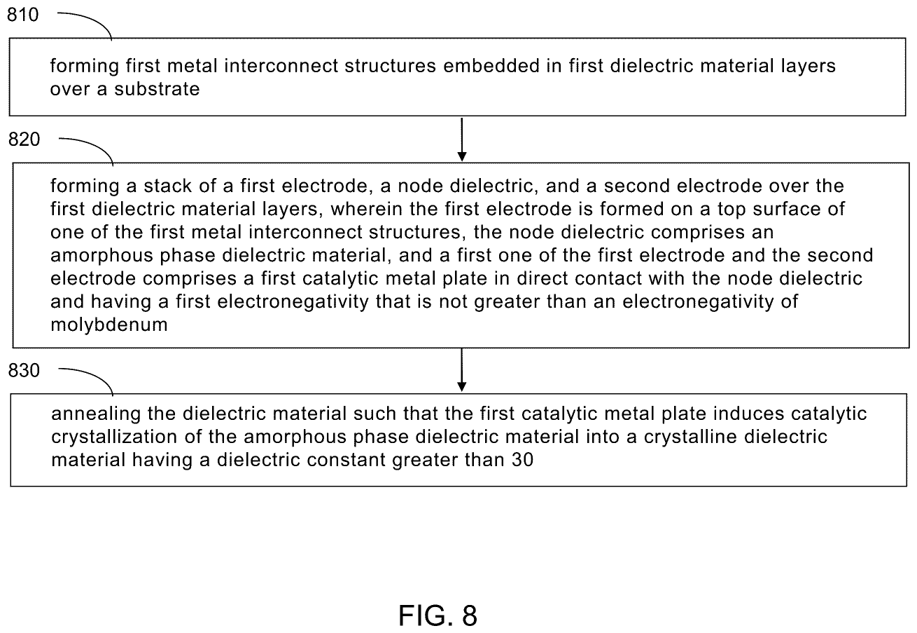

Referring to FIG. 8, a flowchart that illustrates a sequence of processing steps for manufacturing various embodiment resistive memory devices.

Referring to step 810 and FIGS. 1A, 1B, 3A, and 3B, first metal interconnect structures (612, 618, 622, 628, 22) formed within first dielectric material layers (601, 610, 620, 63A) may be formed over a substrate 9.

Referring to step 820 and FIGS. 1C, 2A-2F, and 3C, a stack of a first electrode (32 and/or 33), a node dielectric 35, and a second electrode (37 and/or 38) may be formed over the first dielectric material layers (601, 610, 620, 63A). The first electrode (32 and/or 33) is formed on a top surface of one of the first metal interconnect structures (612, 618, 622, 628, 22). The node dielectric 35 comprises an amorphous phase dielectric material. A first one of the first electrode (32 and/or 33) and the second electrode (37 and/or 38) comprises a first catalytic metal plate (33 or 37) in direct contact with the node dielectric 35 and having a first electronegativity that is not greater than an electronegativity of molybdenum.

Referring to step 830 and FIGS. 2A-2F, 1D, 1E, 1F, 3D, and 3E, the dielectric material may be annealed such that the first catalytic metal plate (33 or 37) induces catalytic crystallization of the amorphous phase dielectric material into a crystalline dielectric material having a dielectric constant greater than 30.

According to an aspect of the present disclosure, the incorporation of a catalytic metal in the second electrode (37 and/or 38) (which may function as a top electrode) and/or in the first electrode (32 and/or 33) (which may function as a bottom electrode) provides a higher dielectric constant for the node dielectric 35, and thus, increases the capacitance of the capacitor structure, particularly at reduced thicknesses of the node dielectric 35. This configuration is advantageous in planar metal-insulator-metal (MIM) capacitors, where a planar layer of the first electrode (32 and/or 33) (which may function as a bottom electrode), a node dielectric 35 comprising a planar dielectric layer, and a planar layer of the second electrode (37 and/or 38) (which may function as a top electrode) are employed. Embodiments of the present disclosure may increase the capacitance of a capacitor structure without using complex three-dimensional MIM structures, which typically require additional mask layers and elevate fabrication costs. Further, although particularly beneficial for planar configurations, embodiments of the present disclosure may also be applied to three-dimensional MIM capacitors, potentially offering even further improvements in capacitance for such three-dimensional MIM capacitors.

Referring to all drawings and according to various embodiments of the present disclosure, a device structure is provided, which comprises: a first electrode (32 and/or 33) overlying a substrate 9; a node dielectric 35 contacting the first electrode (32 and/or 33) and comprising a dielectric material having a dielectric constant greater than 30; and a second electrode (37 and/or 38) contacting the node dielectric 35, wherein a first one of the first electrode (32 and/or 33) and the second electrode (37 and/or 38) comprises a first catalytic metal plate (33 or 37) in direct contact with the node dielectric 35 and having a first electronegativity that is not greater than an electronegativity of molybdenum.

In one embodiment, a predominant volume fraction of the dielectric material is in a symmetrical crystal structure selected from a cubic crystal structure, a tetragonal crystal structure, and a hexagonal crystal structure. In one embodiment, the predominant volume fraction comprises at least 80% of an entire volume of the node dielectric 35.

In one embodiment, a second one of the first electrode (32 and/or 33) and the second electrode (37 and/or 38) comprises a second catalytic metal plate (37 or 33) and having a second electronegativity that is not greater than the electronegativity of molybdenum. In one embodiment, the second catalytic metal plate (37 or 33) is in direct contact with the node dielectric 35. In one embodiment, the first one of the first electrode (32 and/or 33) and the second electrode (37 and/or 38) further comprises a first non-catalytic material plate (32 or 38) having a third electronegativity that is greater the electronegativity of molybdenum and spaced from the node dielectric 35 by the first catalytic metal plate (33 or 37). In one embodiment, the second one of the first electrode (32 and/or 33) and the second electrode (37 and/or 38) comprises a second non-catalytic material plate (38 or 32) having a fourth electronegativity that is greater the electronegativity of molybdenum and spaced from the node dielectric 35 by the second catalytic metal plate (37 or 33).

In one embodiment, the device structure comprises: a first field effect transistor (such as a write transistor WT) located on a top surface of the substrate 9; a second field effect transistor (such as a read transistor RT or a second read transistor RT2) located on the top surface of the substrate 9; and first metal interconnect structures (612, 618, 622, 628, 22) electrically connecting a source/drain region 730 of the first field effect transistor (such as a write transistor WT), a gate electrode 754 of the second field effect transistor (such as a read transistor RT or a second read transistor RT2), and the first electrode (32 and/or 33). In one embodiment, the device structure comprises: first dielectric material layers (601, 610, 620, 63A) embedding the first metal interconnect structures (612, 618, 622, 628, 22); and a planar passivation dielectric layer 63B overlying the first dielectric material layers (601, 610, 620, 63A) and contacting a bottom surface of the first electrode (32 and/or 33). In one embodiment, the device structure comprises a conformal passivation dielectric layer 63C contacting a top surface of the second electrode (37 and/or 38) and contacting sidewalls of the first electrode (32 and/or 33), the node dielectric 35, and the second electrode (37 and/or 38).

According to another aspect of the present disclosure, a device structure is provided, which comprises: a first electrode (32 and/or 33) overlying a substrate 9; a node dielectric 35 contacting the first electrode (32 and/or 33) and comprising a dielectric material, wherein a predominant volume fraction of the dielectric material is in a symmetrical crystal structure selected from a cubic crystal structure, a tetragonal crystal structure, and a hexagonal crystal structure; and a second electrode (37 and/or 38) contacting the node dielectric 35, wherein a first one of the first electrode (32 and/or 33) and the second electrode (37 and/or 38) comprises a first catalytic metal plate (33 or 37) in direct contact with the node dielectric 35 and comprising a metal having a first electronegativity not greater than 1.50.

In one embodiment, the first catalytic metal plate (33 or 37) comprises an alkali metal or an alkaline earth metal. In one embodiment, a second one of the first electrode (32 and/or 33) and the second electrode (37 and/or 38) comprises a second catalytic metal plate (37 or 33) and having a second electronegativity that is not greater than 1.50. In one embodiment, the device structure comprises: a planar passivation dielectric layer 63B contacting a bottom surface of the first electrode (32 and/or 33); and a conformal passivation dielectric layer 63C contacting a top surface of the second electrode (37 and/or 38) and contacting sidewalls of the first electrode (32 and/or 33), the node dielectric 35, and the second electrode (37 and/or 38). In one embodiment, the device structure comprises: first metal interconnect structures (612, 618, 622, 628, 22) electrically connecting the first electrode (32 and/or 33) to a drain region of a first field effect transistor (such as a write transistor WT) located on the substrate 9 and to a gate electrode 754 of a second field effect transistor (such as a read transistor RT or a second read transistor RT2) located on the substrate 9; and second metal interconnect structures (28, EG) electrically connecting the second electrode (37 and/or 38) and electrical ground.

The various embodiments of the present disclosure may be used to provide a capacitor structure 30 having a higher capacitance per unit area without the need for a high temperature anneal above 400 degrees Celsius. Thus, the capacitor structure 30 of various embodiments of the present disclosure are compatible with back-end-of-line processes known in the art. The capacitor structure 30 of the various embodiments of the present disclosure may be used for various application, an example of which is a gain cell memory device using two transistors or three transistors. However, the capacitor structure 30 of various embodiments of the present disclosure may also be used for any application requiring construction of a capacitor structure 30 that is not subjected to thermal cycling at a high temperature such as temperatures higher than 400 degrees Celsius. For example, the capacitor structure 30 of various embodiments of the present disclosure may also be used for dynamic random access memory (DRAM) applications using a capacitor as a charge storage device. In addition, the capacitor structure 30 of various embodiments of the present disclosure may be used for any other application in which a capacitor formed within back-end-of-line structures may be advantageously used for device operation or enhancement of device performance.

The foregoing outlines features of several embodiments so that those skilled in the art may better understand the aspects of the present disclosure. Each embodiment described using the term “comprises” also inherently discloses that the term “comprises” may be replaced with “consists essentially of” or with the term “consists of” in some embodiments, unless expressly disclosed otherwise herein. Whenever two or more elements are listed as alternatives in a same paragraph of in different paragraphs, a Markush group including a listing of the two or more elements may be also impliedly disclosed in some embodiments. Whenever the auxiliary verb “can” is used in this disclosure to describe formation of an element or performance of a processing step, an embodiment in which such an element or such a processing step is not performed is also expressly contemplated, provided that the resulting apparatus or device may provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device structure comprising:
a first electrode overlying a substrate;
a node dielectric contacting the first electrode and comprising a dielectric material having a dielectric constant greater than 30; and
a second electrode contacting the node dielectric,
wherein a first one of the first electrode and the second electrode comprises a first catalytic metal plate in direct contact with the node dielectric and having a first electronegativity that is not greater than an electronegativity of molybdenum.

2. The device structure of claim 1, wherein a predominant volume fraction of the dielectric material is in a symmetrical crystal structure selected from a cubic crystal structure, a tetragonal crystal structure, and a hexagonal crystal structure.

3. The device structure of claim 2, wherein the predominant volume fraction comprises at least 80% of an entire volume of the node dielectric.

4. The device structure of claim 1, wherein a second one of the first electrode and the second electrode comprises a second catalytic metal plate and having a second electronegativity that is not greater than the electronegativity of molybdenum.

5. The device structure of claim 4, wherein the second catalytic metal plate is in direct contact with the node dielectric.

6. The device structure of claim 4, wherein said first one of the first electrode and the second electrode further comprises a first non-catalytic material plate having a third electronegativity that is greater the electronegativity of molybdenum and spaced from the node dielectric by the first catalytic metal plate.

7. The device structure of claim 6, wherein said second one of the first electrode and the second electrode comprises a second non-catalytic material plate having a fourth electronegativity that is greater the electronegativity of molybdenum and spaced from the node dielectric by the second catalytic metal plate.

8. The device structure of claim 1, further comprising:
a first field effect transistor located on a top surface of the substrate;
a second field effect transistor located on the top surface of the substrate; and
first metal interconnect structures electrically connecting a source/drain region of the first field effect transistor, a gate electrode of the second field effect transistor, and the first electrode.

9. The device structure of claim 8, further comprising:
first dielectric material layers embedding the first metal interconnect structures; and
a planar passivation dielectric layer overlying the first dielectric material layers and contacting a bottom surface of the first electrode.

10. The device structure of claim 9, further comprising a conformal passivation dielectric layer contacting a top surface of the second electrode and contacting sidewalls of the first electrode, the node dielectric, and the second electrode.

11. A device structure comprising:
a first electrode overlying a substrate;
a node dielectric contacting the first electrode and comprising a dielectric material, wherein a predominant volume fraction of the dielectric material is in a symmetrical crystal structure selected from a cubic crystal structure, a tetragonal crystal structure, and a hexagonal crystal structure; and
a second electrode contacting the node dielectric,
wherein a first one of the first electrode and the second electrode comprises a first catalytic metal plate in direct contact with the node dielectric and comprising a metal having a first electronegativity not greater than 1.50.

12. The device structure of claim 11, wherein the first catalytic metal plate comprises an alkali metal or an alkaline earth metal.

13. The device structure of claim 11, wherein a second one of the first electrode and the second electrode comprises a second catalytic metal plate and having a second electronegativity that is not greater than 1.50.

14. The device structure of claim 11, further comprising:
a planar passivation dielectric layer contacting a bottom surface of the first electrode; and
a conformal passivation dielectric layer contacting a top surface of the second electrode and contacting sidewalls of the first electrode, the node dielectric, and the second electrode.

15. The device structure of claim 11, further comprising:
first metal interconnect structures electrically connecting the first electrode to a drain region of a first field effect transistor located on the substrate and to a gate electrode of a second field effect transistor located on the substrate; and
second metal interconnect structures electrically connecting the second electrode and electrical ground.

16. A method of forming a device structure, the method comprising:
forming first metal interconnect structures formed within first dielectric material layers over a substrate;
forming a stack of a first electrode, a node dielectric, and a second electrode over the first dielectric material layers, wherein the first electrode is formed on a top surface of one of the first metal interconnect structures, the node dielectric comprises an amorphous phase dielectric material, and a first one of the first electrode and the second electrode comprises a first catalytic metal plate in direct contact with the node dielectric and having a first electronegativity that is not greater than an electronegativity of molybdenum; and
annealing the dielectric material such that the first catalytic metal plate induces catalytic crystallization of the amorphous phase dielectric material into a crystalline dielectric material having a dielectric constant greater than 30.

17. The method of claim 16, wherein a predominant volume fraction of the crystalline dielectric material is in a symmetrical crystal structure selected from a cubic crystal structure, a tetragonal crystal structure, and a hexagonal crystal structure.

18. The method of claim 17, wherein the predominant volume fraction comprises at least 80% of an entire volume of the node dielectric.

19. The method of claim 16, wherein a second one of the first electrode and the second electrode comprises a second catalytic metal plate and having a second electronegativity that is not greater than the electronegativity of molybdenum.

20. The method of claim 16, further comprising:
forming a first field effect transistor on a top surface of the substrate; and
forming a second field effect transistor on the top surface of the substrate, wherein the first metal interconnect structures electrically connect a source/drain region of the first field effect transistor, a gate electrode of the second field effect transistor, and the first electrode.
